(19) United States
(12) Patent Application Publication
(10) Pub. No.: US 2007/0097388 A1
(43) Pub. Date: May 3, 2007

(54) Image reading device

(76) Inventor: Tatsuo Noda, Osaka (JP)

Correspondence Address: GLOBAL IP COUNSELORS, LLP, 1233 20TH STREET, NW, SUITE 700, WASHINGTON, DC, 20036-2680, US

(21) Appl. No.: 11/258,886

(22) Filed: Oct. 27, 2005

(51) Int. Cl. G03F 3/08

(52) U.S. Cl. 358/1.9; 358/518

(57) ABSTRACT

A standard density display means for displaying to a user a standard density for reading images of a standard color based on a set reading density is provided. Furthermore, the standard density display means is programmed so as to display a standard density read button for executing an image reading at the standard density, and configured so as to read images at the standard density when this button is selected regardless of the set reading density.

### FIELD OF THE INVENTION

The present invention relates to an image reading apparatus, such as a scanner, copying machine, and multi function machine, for reading text documents, photographs and the like.

### BACKGROUND INFORMATION

Scanners, copying machines and multi function machines have rapidly come to be widely used in offices and homes in recent years, and used for various purposes either as stand alone machines or connected to a personal computer (PC) or the like. Among these devices, scanners are exclusively for reading images, however, copiers and multi function machines also have an image reading function as a basic function.

Copying machines read a document image once and store the image in memory as image data, and the stored image data are formed again as an image on printing paper; multi function machines may use the image data for various purposes, such as facsimile transmission and the like.

When an image is read in this case, although the density of a document is often read at a standard density that faithfully reflects the density of the document image directly (standard color), the user may set the reading density according to need.

Normally, when an image is read, a reading display is provided, such as that shown in FIG. 2, on a touch panel of the image reading apparatus body, or on the screen of a PC connected to the image reading apparatus over a network. When reading an image at a set density (standard density), the user selects [automatic] button 21, and the user selects the [manual] button 22 to reset the density. In the latter case, the reading density can be set [lower] or [higher] by moving a cursor PI by operating the buttons 23 and 24. A density display unit 26 is a bar graph type display with a scale from 1 to 7 that schematically represents the reading density.

Although the user can set the reading density in this way, a [default setting] button 25 can be selected when it is too troublesome to set the density to read the image using the screen shown in FIG. 2. Then, a density setting screen, such as shown in FIG. 3, appears on the touch panel or PC screen.

The reading density is displayed as a number line scale ranging from −3 to +3 in the density setting screen, and the reading is performed at the standard density at the scale 0 position.

When reading a newspaper, for example, only the typeface part is read and the background color of the newspaper is not required in the image. At such a time, the user touches (or clicks) the button 31, to select, for example, a reading density of −2. Then, the image is read at a density two levels lower than the standard density. At this time, a cursor P2 that indicates the value of the reading density moves from level 0 to level −2 on the scale. Furthermore, the reading density set by the user using the screen shown in FIG. 3 is stored on the image reading apparatus, and can be used in subsequent readings. Thus, it is possible to avoid performing a complex density setting each time when the same type of document is handled frequently, as in an office or the like.

As described above, the setting of a reading density by a user, and the storage of a user-set reading density in the image reading apparatus are known prior art.

The following problems occur in the known art, however.

Certainly, the storage of a user-set reading density in the image reading apparatus has the advantage of avoiding the complexity of setting the density each time when the same type of document is handled frequently, as in an office or the like. However, when a document must be read at the standard density, the image reading apparatus may be operated with the currently set density, and the operation must then be repeated in such cases.

Although displaying the density setting screen shown in FIG. 2 each time an image is read has been considered in order to avoid the previously described mistake, such would require ignoring the aim of avoiding the complexity of setting the density each time by storing the reading density in the image forming apparatus.

In view of these problems, an object of the present invention is to provide an image reading apparatus that clearly indicates at a glance, whatever the set density, the capability of executing image reading at a standard density when a user-set reading density is different from a standard density.

### SUMMARY OF THE INVENTION

The present invention uses the following means to attain these objects.

The present invention provides an image reading apparatus provided with a density setting means for setting a reading density when reading a document as described above. In this image reading apparatus, a standard density display means is provided for displaying to the user a standard density for reading images of a standard color based on a set reading density. In this way the density of an document image of a standard color is specified.

Furthermore, the standard density display means is programmed so as to display a standard density read button for executing an image reading at the standard density. That is, when this button is selected, image reading can be performed at a standard density regardless of the user-set density.

As described above, the image reading apparatus of the present invention clearly indicates at a glance that image reading can be executed at a standard density when a user-set reading density is different from a standard density, thus avoiding the complexity of setting the density each time an image is read.

### BRIEF DESCRIPTION OF THE DRAWINGS

FIGS. 1A and 1B are examples of a reading display for the image reading apparatus of the present invention;

FIG. 2 is an example of a reading display of a conventional image reading apparatus; and

FIG. 3 is an example of the density setting screen of a conventional image reading apparatus.

### DETAILED DESCRIPTION OF THE PREFERRED EMBODIMENTS

The preferred embodiments of the present invention are described hereinafter with reference to the drawings.

First, the present invention provides an image reading apparatus provided with a density setting means for setting a reading density for reading a document as described above. Normally, when an image is read, a reading display is provided, such as that shown in FIG. 2, on a touch panel of the image reading apparatus body, or on the screen of a personal computer (PC) connected to the image reading apparatus over a network.

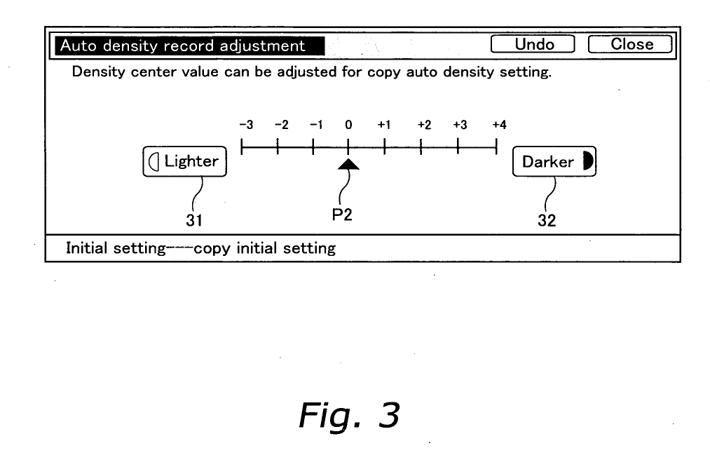

When reading an image at a set density (standard density), the user selects [automatic] button 21, and the user selects the [manual] button 22 to reset the density. In the latter case, the reading density can be set [lower] or [higher] by moving a cursor P1 by operating the buttons 23 and 24. A density display unit 26 is a bar graph type display with a scale from 1 to 7 to schematically represent the reading density. Although the user can set the reading density in this way, a [default setting] button 25 can be selected when it is too troublesome to set the density to read the image using the screen shown in FIG. 2. Then, a density setting screen, such as shown in FIG. 3, for example, appears on the touch panel or PC screen.

The reading density is displayed as a number line scale ranging from −3 to +3 in the density setting screen, and the reading is performed at the standard density at the scale 0 position.

When reading a newspaper, for example, only the typeface part is read and the background color of the newspaper is not required in the image. At such a time, the user touches (or clicks) the button 31, to select, for example, a reading density of −2. Then, the image is read at a density two levels lower than the standard density. At this time, a cursor P that indicates the value of the reading density moves from level 0 to level −2 on the scale. Furthermore, the user-set reading density is stored in the image reading apparatus and can be used in subsequent image reading. Of course, the above-mentioned newspaper is one example, and in instances of reading documents printed on colored paper, and notes with faint background patterns there are numerous practical examples.

Similar to setting density in the prior art, the image reading apparatus of the present invention starts a standard density display means for displaying to a user a standard density for reading images of a standard color (the immediate color of the document image). The standard density display means is a program stored in memory, and operates as described below.

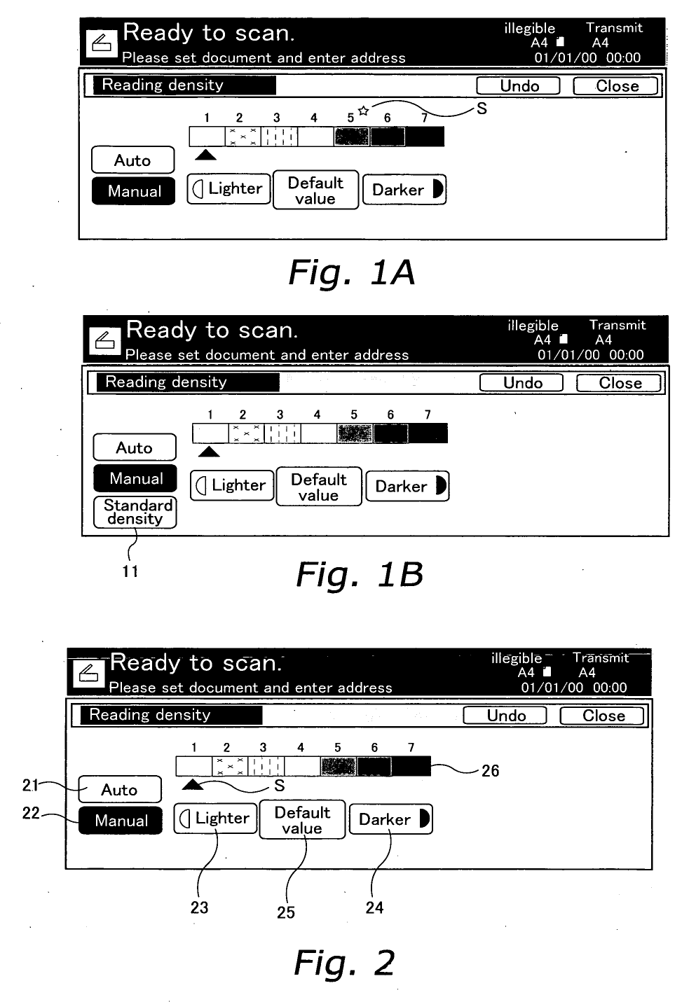

When a set reading density is different from the standard density, whatever the set density, the capability of executing image reading at the standard density is indicated to the user by the star symbol of the standard density indicated by an S in the reading display of the density display unit 26, as shown in Fig. 1A. In this example, reading can be performed at the standard density when density 5 is selected.

In this way, when temporarily reading a document at a standard density in an office where mainly newspapers are read, for example, the user can clearly understand at a glance that image reading can be performed at the standard density, whatever the set density, without confirming the density setting in detail.

Although the standard density indicated by the mark S star symbol is only an example, any display mark may be used insofar as the display is understood by the user.

The following configuring is also possible. A standard density reading button 11 [standard density] is displayed, as shown in Fig. 1B. The previously mentioned standard density display means can be programmed so as to perform reading at the standard density whenever this button is selected.

In this way image reading can be performed at a standard density simply and quickly even when a set reading density is different from the standard density.

The image reading apparatus of the present invention can be used in scanners, copying machines, and multi function machines, and permits a user to understand at a glance that image reading can be performed at a standard density, whatever the set density, when a set density is different from the standard density, thereby avoiding the complexity of setting the density each time an image is read.

What is claimed is:

1. An image reading apparatus provided with a density setting means for setting the reading density for reading an image, the image reading apparatus comprising:
a standard density display means for displaying to a user a standard density for reading images of a standard color based on a set reading density.

2. The image reading apparatus of claim 1, wherein the standard density display means displays a standard density read button for executing an image reading at the standard density.
